(19) United States
(12) Patent Application Publication
(10) Pub. No.: US 2002/0153529 A1
(43) Pub. Date: Oct. 24, 2002

(54) LED array with optical isolation structure and method of manufacturing the same

(76) Inventor: Jin-Shown Shie, Hsin Chu (TW)

Correspondence Address: MARTINE & PENILLA, LLP, 710 LAKEWAY DRIVE, SUITE 170, SUNNYVALE, CA, 94085, US

(21) Appl. No.: 09/841,882

(22) Filed: Apr. 24, 2001

(51) Int. Cl. H01L 21/00

(52) U.S. Cl. 257/88

(57) ABSTRACT

A Light Emitting Diode array (LED) with an optical isolation structure and a method of manufacturing the same. The LED array with an optical isolation structure includes a substrate, a plurality of LED units and a plurality of trenches. The plural LED units and trenches are disposed on the surface of the substrate. Each trench is disposed between every two LED units and deposited with at least one reflective metal layer. The substrate of the LED array with an optical isolation structure is formed of a low-energy-gap semiconductor material, while the LED units are formed by another kind of semiconductor material whose energy gap is higher than the substrate. The light emitted from each LED unit is reflected by the plural trenches deposited with at least one reflective metal layer, and absorbed by the substrate with low-energy gap.

### BACKGROUND OF THE INVENTION

1. Field of the Invention

The present invention relates to an LED array for the LED display or the LED printer and the method of fabrication the same. Especially, the present invention is about an LED array with an optical isolation structure and a method fabricating thereof with a reduced cost.

2. Description of the Related Art

Light emitting diodes (LEDs) have been widely used in many indicators, such as “ON/OFF” sign on the power switches. Nowadays, the brightness of LEDs has been greatly improved and the blue-light LED has been well developed. Besides, the LEDs are characterized by their extended long life, low energy consumption and low heat generation. Therefore, it becomes increasingly popular to utilize the light emitting diodes as illuminating sources, such as LED display panels or traffic light indicators etc.

As described above, a plurality of LEDs can be arranged in a row or a matrix to construct a large-scale LED display or panel, such as described in U.S. Pat. No. 4,628,422 and U.S. Pat. No. 4,851,824. In such a large-scale LED apparatus, the plural LEDs can be assembled with the conventional package technology. However, when the LED apparatus becomes smaller, such as the LED array in a LED printer head or the LED array in a head mounted display, the size of each LED in the apparatus becomes very small therefore the packaging process becomes more complicated, see U.S. Pat. No. 5,014,074. Furthermore, such a small-scale LED apparatus which utilizes two-dimensional LED arrays to display images usually contains more than ten thousands LEDs. Therefore, the process of assembling each LED into the precise position usually takes longer time and higher cost than that of the LEDs manufacturing process.

Further, the apparatuses that utilize the LEDs as the light source are reduced in their size, such as in the LED printer heads, an LED array is utilized as the electro-optical scanning tool instead of the mechanically spinning polygonal mirror. The spinning polygonal mirror assembled in the traditional laser printers occupies much space and increases the package size of the laser printer. For example, if a laser printer is manufactured with the spinning polygonal mirror as the scanning tool for poster size, the dimension of the entire assembly must be over the poster to be printed due to the existence of printer's fly-back plat form. On the other hand, the LED printer for the same size of the poster only requires the necessity of being as wide as the poster to be printed, the other dimension, the length, is drastically reduced as current rolling-type printer. Therefore, the size of the LED printer is much smaller than the laser printer. However, there are some drawbacks within the LED printers. The most obvious one is the cross-talk phenomenon between neighboring LED dice arranged in an array chip that comes from the light transmitting through the boundary layers thereof, and decreases the image resolution of the LED array. This phenomenon also exists when array LED chips are utilized for LED monitors.

Summing up the above, it is desirable to set up a process that can simplify the manufacturing process of LED arrays, and avoid the cross-talk phenomenon therein.

### SUMMARY OF THE INVENTION

Therefore, one object of the present invention is to provide a LED array chip with an optical isolation structure, which prevents the light emitted from each LED pixel from transmitting into the areas of neighboring LEDs and increases the image resolution thereof.

Further, another object of the present invention is to provide a method of fabricating a LED array with an optical isolation structure. The LED array is constructed by forming a plurality of LED units on the same substrate with a semiconductor process. The complicated packaging process is simplified and therefore, the cost of LED array manufacturing process is reduced.

According to the present invention, the LED array with an optical isolation structure includes a substrate, a plurality of LED units and a plurality of trenches. The substrate is made of a semiconductor material with low energy gap. The plural LED units are formed on the substrate, and each LED unit having a PN junction layer made of a semiconductor material whose energy gap is higher than the substrate. The plural trenches are formed on the substrate. Each trench is disposed between every two adjacent LED units, and the depth of each trench is larger than the that of the LED junction. A first insulation layer is deposited on the entire surface of the substrate, including the surface of each LED unit and each trench. A first reflective metal layer is deposited on the surface inside each trench, and overlaid on the first insulation layer formed inside each trench. A second insulation layer is deposited on the surface of the first reflective metal layer formed inside each trench, and is used to refill each trench and planarize the entire surface of the substrate. A passivation layer is formed on the entire surface of the substrate. A plurality of contact windows are formed on the surface of the plural LED units. Each contact window is etched through the passivation layer and the first insulation layer deposited on each LED unit, and is used to expose part of the PN junction layer of each LED unit for electrical connectivity. A plurality of metal bonding pads are formed on the substrate, and connected to the surface of the PN junction layer inside the plural contact windows. And, a backside metal layer is formed on the backside of the substrate for one of the external electrical conduction.

In the LED array of the present invention, the light emitted from each LED unit transfers in the transverse direction is reflected by the reflective metal layer formed on the walls of the plural trenches. Similarly, the light emitted from each LED unit transfers downwardly is absorbed by the substrate whose energy gap is lower than the PN junction layer of the plural LED units. Consequently, the cross-talk phenomenon in the traditional light emitting diode arrays that resulted from the light disturbance between adjacent LED units is avoided. Hence, the image resolution of the LED array is improved.

According to the present invention, the LED array is constructed by forming a plurality of LED units on the same substrate with a semiconductor process. The step of assembling each LED unit into the precise position of the traditional LED array manufacturing process is omitted. Therefore, the LED array manufacturing process is simplified and the cost thereof is reduced.

The objects, features and advantages of the present invention will become more apparent with reference to the accompanying drawings and the following detailed descriptions.

### BRIEF DESCRIPTION OF THE DRAWINGS

FIG. 1 is a cross-sectional view illustrating the various optical paths in cross-talk phenomenon in the traditional LED arrays;

FIG. 2 is a plan view illustrating a 2×N LED array of the preferred embodiment according to the present invention;

FIG. 3 is a plan view illustrating a N×N LED array of the preferred embodiment according to the present invention;

FIG. 4 is a cross-sectional view illustrating a 2×N LED array of the preferred embodiment possesses the advantage of optical isolation according to the present invention;

FIGS. 5A to 5C is a flow chart illustrating the manufacturing process of the LED array of the preferred embodiment according to the present invention;

FIG. 6 is a three dimensional view of a 2×N LED array of the preferred embodiment according to the present invention.

### DETAIL DESCRIPTION OF THE INVENTION

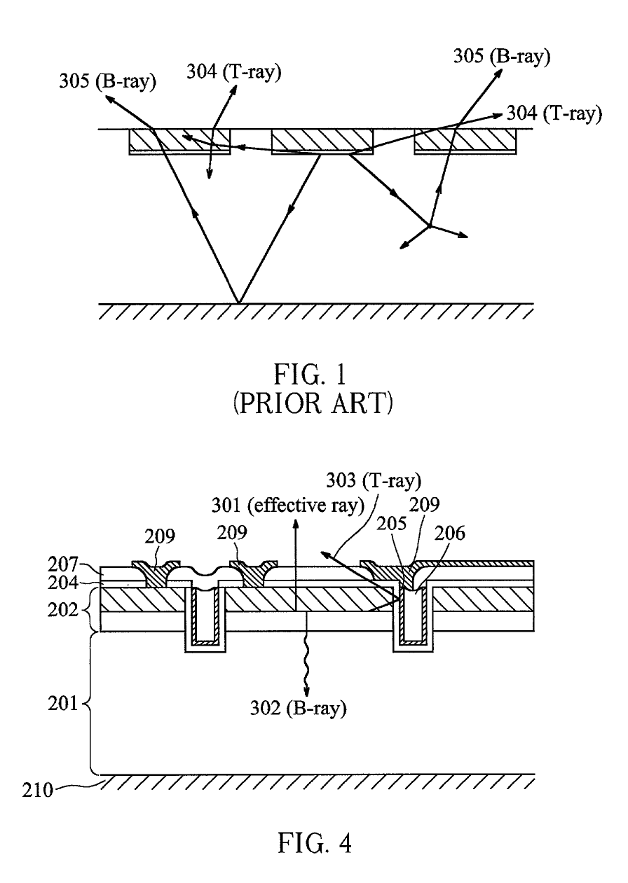

Referring to FIG. 1, the light transmitting routes and the cross-talk phenomenon in the traditional LED arrays are illustrated. As shown in FIG. 1, the lights emitted from a LED unit of the traditional LED array transmit into the surrounding LED units in two routes: One is called T-ray, which transferring in the transverse direction, transmitting through the boundary layer and emitting from the surface of the adjacent LEDs; and the other is called B-ray, which transferring downwardly to the base, transmitting through the substrate, reflected by the backside metal layer, and emitting from the surface of the adjacent LEDs. Thus, the light emitted from each LED is disturbed by T-rays and B-rays, and the image resolution of the LED array is decreased. This is called the cross-talk phenomenon in the traditional LED arrays, which can seriously damage the display resolution when high density array is designed.

Therefore, the present invention is to provide a LED array with an optical isolation structure that avoids the cross-talk phenomenon in the traditional LED array by utilizing the trench technology in semiconductor process. Now, the LED array according to the preferred embodiment of the present invention and the method of fabricating the same will be described below.

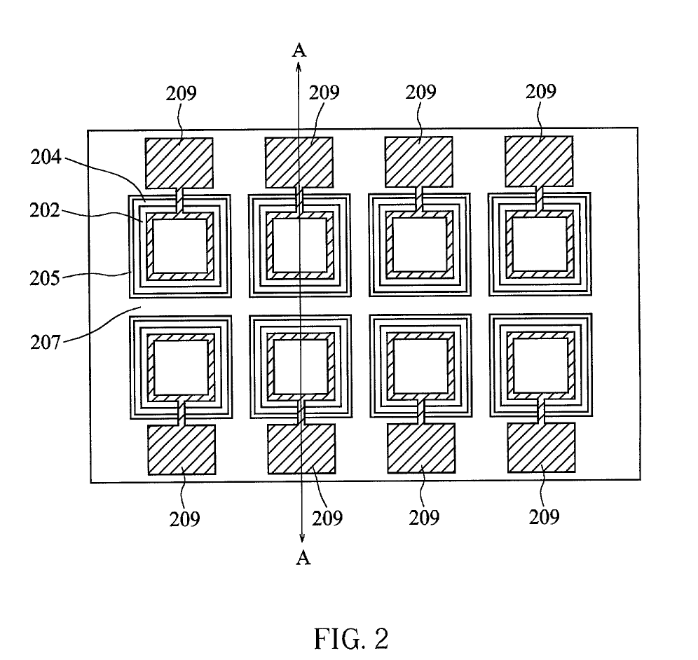

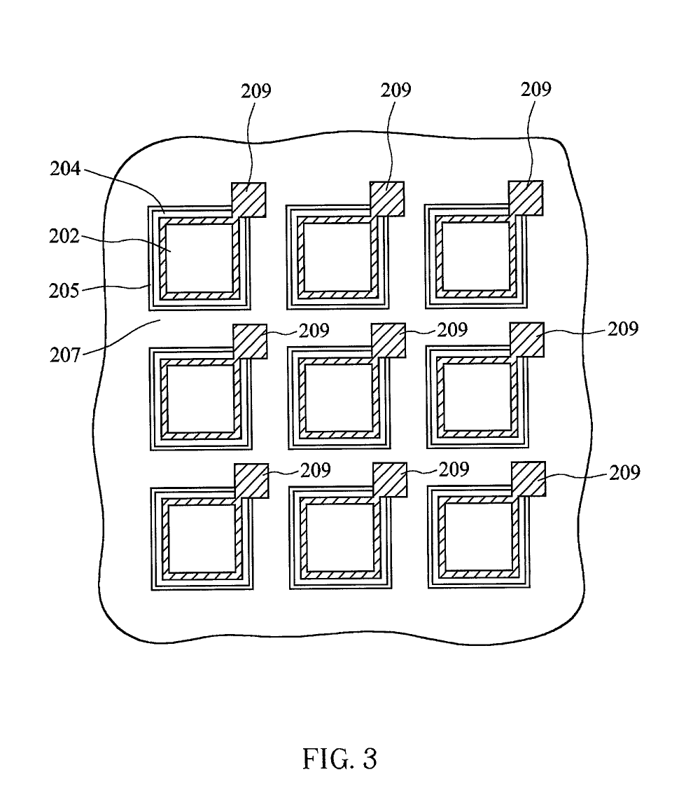

Please refer to FIG. 2 and FIG. 3. FIG. 2 is a plat view of a 2×N LED array according to the preferred embodiment of the present invention, and FIG. 3 is a plat view of a N×N LED array according to another embodiment of the present invention.

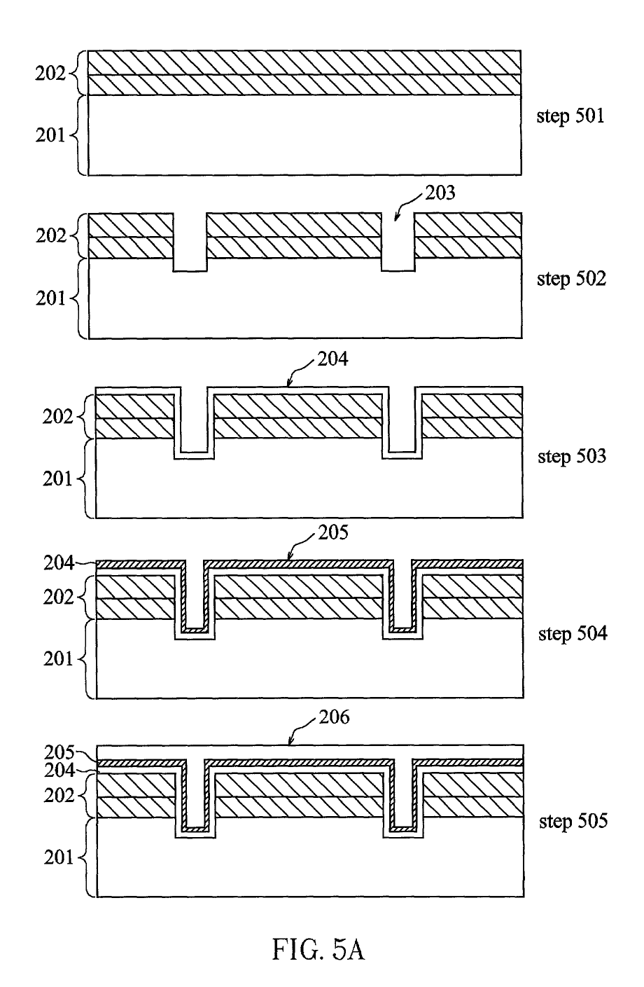

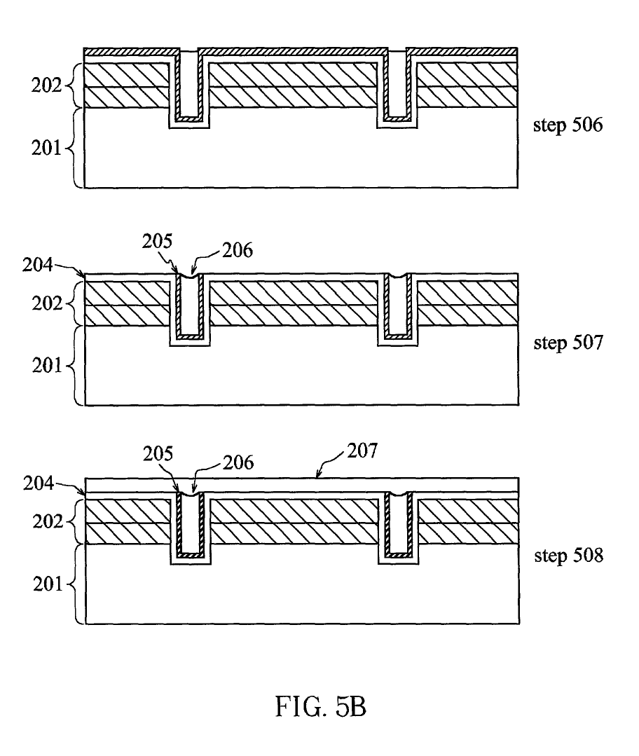

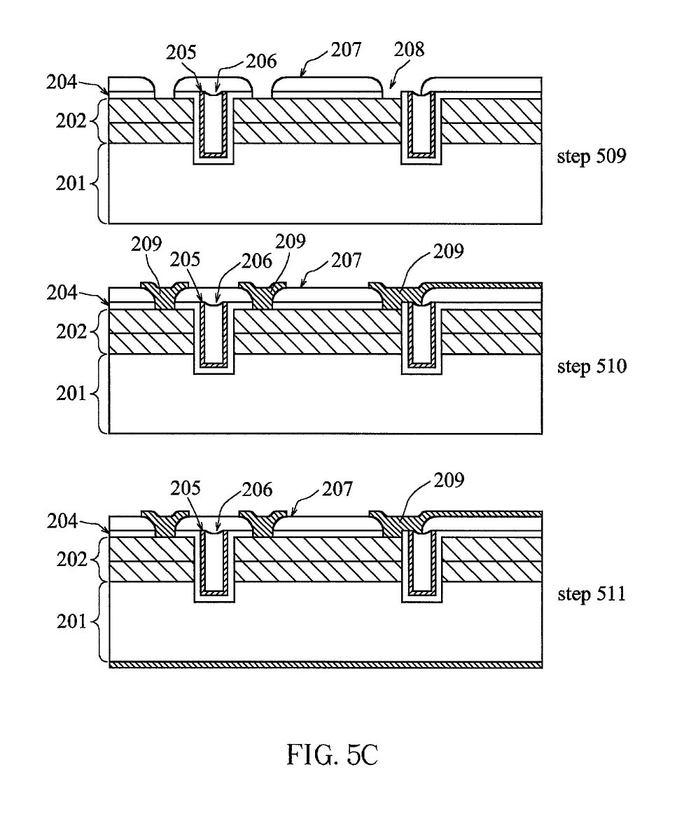

Referring to FIG. 4, a cross-sectional view of a 2×N LED array along a cutting line A-A shown in FIG. 2 is illustrated. Then referring to FIGS. 5A to 5C, the manufacturing process of the LED array of the present invention is shown in sequence. The structure and the manufacturing process of the LED array of the preferred embodiment will be described below. In these figures, the same notations are referred to the same part of the LED array.

According to the present embodiment, the substrate of the LED array is made of III-V compound semiconductor materials with low energy gap, for example, a GaAs wafer is prepared as the substrate 201 of the LED array. Then, a film of III-V compound semiconductor epitaxial layer whose energy gap is higher than the substrate is formed on the surface of the GaAs substrate 201 with the epitaxy technology, for example, a AlGaAs epitaxial layer is deposited on the substrate 201. Then, the AlGaAs epitaxial layer is transformed into a PN junction layer 202 through a PN junction process (see FIG. 5A, step 501). The PN junction layer 202 formed on the substrate is the main structure of each LED unit of the LED array of the present embodiment.

Then, a plurality of LED units are formed on the substrate with a well-known trench technology in semiconductor process.

First, a film of positive photoresist is coated on the surface of the PN junction layer 202. Then, a plurality of LED unit areas are defined on the surface of the positive photoresist with a first photo mask by the well-known photolithography technology. The exposed PN junction layer 202 and part of the substrate 201 are etched away through a well-known etching process. Then, the photoresist is removed. In this step, a plurality of trenches 203 are formed on the substrate 201 and a plurality of LED units are formed in the plural defined LED unit areas. (see FIG. 5A, step 502) The depth of each trench 203 is larger than the depth of the PN junction layer 202. The plural trenches are fabricated as a net-like structure on the substrate as shown in FIG. 2 and FIG. 3. In this manner, the plural LED units of a 2×N array or a N×N array are formed on the same substrate at the same time, and the assembling process of each LED into the precise position in the traditional LED array manufacturing process is omitted.

Then, the process of constructing an optical isolation structure in a 2×N LED array or a N×N LED array according to the present embodiment is described below.

First, a film of Silicon Oxide(SiO₂) or Silicon Nitride(SiNx) is deposited on the entire surface of the substrate as a first insulation layer 204 with the well-known chemical vapor deposition process. (see FIG. 5A, step 503 ) The first insulation layer 204 is used to make the plural LED units to be insulated with each other. Further, the first insulation layer 204 is used to prevent the P/N terminal of the PN junction layer conducting with each other through a metal layer. Hence, the short-circuit problems in the LED array is avoided.

Thereafter, a metal film, such as gold(Au) or Aluminum(Al), is deposited on the entire surface of the first insulation layer 204 as a first reflective metal layer 205 (see FIG. 5A, step 504). The first reflective metal layer 205 is used to prevent the light emitted from each LED unit from transmitting through the boundary layer, i.e. the trenches 203, and transferring into the areas of the adjacent LED units.

Then, after the deposition of the first reflective metal layer 205, the substrate 201 provided with the plural LED units, the plural net-like trenches 203, the first insulation layer 204 and the first reflective layer 205 is processed with a planarization process. The entire surface of the substrate 201 is spinning coated with a film of Spin-On Glass (SOG). Thus, the plural net-like trenches are refilled with SOG as the second insulation layer 206 (see FIG. 5A, 505). Then, the substrate 201 is processed with an etching-back process. The SOG layer is etched back until the first reflective layer 205 on the surface of the plural LED units is exposed (see FIG. 5B, 506). This etching-back process is used to form a planar surface on the substrate 201. Therein, a polyimide may be used as the alternative material of the second insulation layer 206.

Then, the substrate is processed with a metal etching process. Part of the first reflective metal layer 205 is removed. The first reflective metal layer 205 exposed on the surface of the PN junction layer 202 is etched away with a well-known etching technology. Thus, the surface of the PN junction layer 202 of each LED unit is exposed to the air (see FIG. 5B, step 507). The first insulation layer 204 on the surface of each LED unit is remained. The first insulation layer 204 is transparent. Thus, the transmitting route of the light emitted from each LED unit is not affected by the first insulation layer 204 deposited on the PN junction layer 202. Part of the first reflective metal layer 205 is also remained. The first reflective layer 205 deposited on the surface inside each trench 203 is remained after the metal etching process.

According to descriptions mentioned above, the first insulation layer 204, the first reflective metal layer 205 and the second insulation layer 206 are constructed in the plural net-like the trenches 203 disposed between the plural LED units and thus constitute an optical isolation structure on the substrate 201. The depth of the optical isolation structure, in which a first reflective metal layer 206 is provided, is larger than the depth of the PN junction layer 202 of the plural LED units. Consequently, when the light emitting from each LED unit transfers toward the transverse directions of the unit, namely T-rays, the light transmits through the first insulation layer 204 next to the emitting LED unit, and irradiates on the first reflective layer 205 next to the insulation layer 204. Then, the light is reflected by the first reflective metal layer 205, and returns back into the area of the original emitting LED unit. Further, the substrate of the LED array of the present embodiment is made of the material whose energy gap is lower than the material of the PN junction layer of the plural LED units, i.e. the substrate is made of GaAs, and the PN junction layer is made of AlGaAs. Therefore, when the light emitting from each LED unit and transfers downwardly, namely B-rays, is absorbed by the substrate 201 whose low energy gap. Thus, the cross-talk phenomenon in the traditional LED arrays is avoided by the optical isolation structure of the LED array of the present invention successfully.

Then, a film of Silicon Nitride (SiNx) is deposited on the entire surface of the substrate as a passivation layer 207 (see FIG. 5B, step 508). The passivation layer 207 is used a protection film to prevent the LED array from being damaged. Thereafter, a film of positive photoresist is coated on the surface of passivation layer 207. Then, a plurality of contact window areas are defined on the surface of the positive photoresist with a second photo mask by the well-known photolithography technology. The passivation layer 207 and the first insulation layer 204 that exposed to the contact window areas are etched away through a well-known etching process. Then, the photoresist is removed. In this step, a plurality of contact windows 208 are formed on the surface of the plural LED units, and part of the surface of the PN junction layer 202 are exposed to the air through the plural contact windows. (see FIG. 5C, step 509 ).

Then, a metal film, for example, an Al film is deposited on the entire surface of the substrate as the second metal film. Thereafter, a film of positive photoresist is coated on the surface of second metal film. Then, a plurality of bonding pad areas are defined on the surface of the positive photoresist with a third photo mask by the well-known photolithography technology. Part of the second metal layer is removed through a metal etching process, while part of the second metal layer defined in the bonding pad areas are remained. Then, the photoresist is removed. In this step, a plurality of metal bonding pads 209 are formed on the surface of the substrate 201. The plural metal bonding pads 209 are used to connect to the surface of the PN junction layer of the plural LED units. (see FIG. 5C, step 510).

Further, a third metal film, for example, an Al film is deposited on the backside of the substrate as a backside metal layer 210.(see FIG. 5C, step 510) The backside metal layer 210 is used to reflect the light emitted from each LED unit transferring downwardly, namely B-rays.

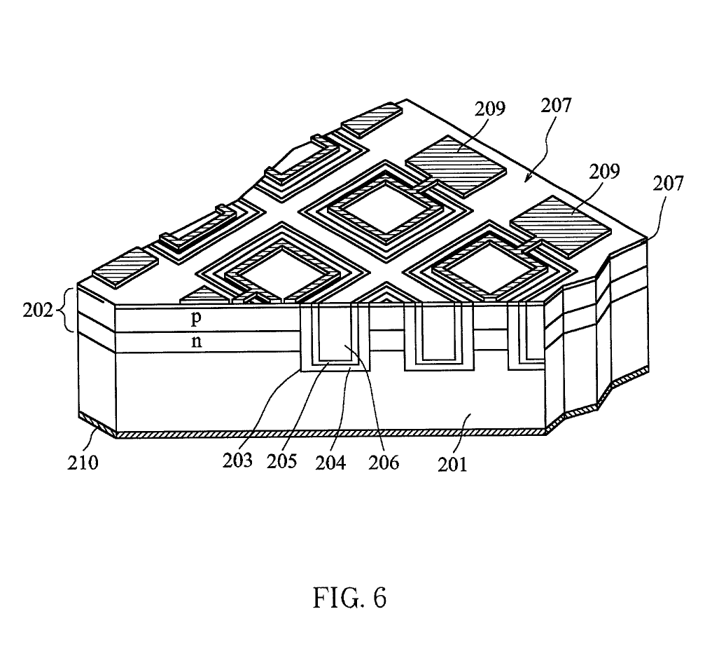

The resulting structure of the LED array is shown in FIG. 6. In this figure, the drawings are simplified and only several LED units in the LED array are drawn. As shown in the FIG. 6, a LED unit located on the substrate 201 is surrounded by a net-like trench 203. The trench 203 is constructed by the first insulation layer 204, the first reflective metal layer 205 and the second insulation layer. The substrate 201 is made of a semiconductor material whose energy gap lower than the PN junction layer 202. Further, a backside metal layer 210 is disposed on the backside of the substrate 201. When an electric current flows through the metal bonding pad 209, it activates the PN junction layer 202 in the plural LED units. (not shown) The lights are emitted from the PN junction layer 202 in the plural LED units and transfer in various directions. In the traditional LED arrays, as shown in FIG. 1, the cross-talk phenomenon is occurred because of T-rays, which transferring in transverse directions, and B-rays, which transferring downwardly. On the other hand, according to the LED array of the present invention, the lights transferring in the transverse directions are reflected by the first reflective metal layer deposited on the surface inside the surrounding trenches; and the lights transferring downwardly are absorbed by the substrate whose low energy gap.

Therefore, according to the LED array of the present invention, the cross-talk phenomenon in the traditional LED arrays is avoided. Further, the plural LED units of the LED array of the present invention are formed on the same substrate at the same time with a semiconductor process. Therefore, the complicated process for assembling each LED unit into the precise position is omitted. In this way, the manufacturing process of the LED array is simplified and the cost of manufacturing the same is reduced.

While preferred embodiments of the present invention have been described above, such description is for illustrative purposes only, and it is to be understood that changes and variations may be made without departing from the spirit or scope of the following claims.

What is claimed is:

1. A light emitting diode array with an optical isolation structure, comprising:
a substrate made of a semiconductor material;
a plurality of light emitting diode units formed on said substrate, therein, each light emitting diode unit having a PN junction layer made of a semiconductor material whose energy gap is higher than said substrate;
a plurality of trenches formed on said substrate, each trench is located between every two adjacent said light emitting diode units and used to isolate said adjacent plural light emitting diode units, therein, the depth of said trenches is larger than the depth of said light emitting diode units;
a first insulation layer formed on said substrate, said first insulation layer is formed on the surface of said plural light emitting diode units and on the surfaces inside said plural trenches;
a first reflective metal layer formed on said substrate, said first reflective metal layer is formed on the surface inside said plural trenches and overlaid on the first insulation layer formed inside said plural trenches
a second insulation layer formed on said substrate, said second insulation layer is formed on the surface inside said plural trenches and overlaid on the first reflective metal layer formed inside said plural trenches;
a passivation layer formed on said substrate, said passivation layer is overlaid on the surface of the first insulation layer formed on said plural light emitting diode units, and on the surface of the second insulation layer formed inside said plural trenches;
a plurality of contact windows formed on said plural light emitting diode units, therein, said plural contact windows are etched through the passivation layer and the first insulation layer on said plural light emitting diode units, making part of the PN junction layer of said plural light emitting diode units exposed to said contact windows;
a plurality of metal bonding pads formed on said substrate, therein, said plural metal bonding pads are connected to the PN junction layers of said plural light emitting diode units through said plural contact windows; and
a backside metal layer, formed on the backside of said substrate.

2. The light emitting diode array according to claim 1, therein, said substrate is formed of III-V compound semiconductor materials.

3. The light emitting diode array according to claim 1, therein, the PN junction layer of said plural light emitting diode units is formed of Ill-V compound semiconductor materials whose energy gaps are higher than said substrate.

4. The light emitting diode array according to claim 1, therein, said first insulation layer is formed of silicon nitride or silicon oxide.

5. The light emitting diode array according to claim 1, therein, said second insulation layer is formed of polyimide or spin-on glass.

6. The light emitting diode array according to claim 1, said light emitting diode array is used as a light emitting module in the printer head.

7. The light emitting diode array according to claim 1, said light emitting diode array is used as the red, blue or green light emitting modules in the head mounted display.

8. A method of fabricating a light emitting diode array with an optical isolation structure, comprising:
preparing a substrate, said substrate is made of a semiconductor material;
forming a epitaxy layer on the surface of said substrate, said epitaxy layer is made of semiconductor material whose energy gap is higher than said substrate;
transforming said epitaxy layer into a PN junction layer;
patterning a plurality of light emitting diode unit areas on the surface of said PN junction layer with photolithography technology;
forming a plurality of trenches and a plurality of light emitting diode units by removing the PN junction layer and part of said substrate disposed in said plural light emitting diode unit areas, therein, the depth of said plural trenches is larger than the depth of said PN junction layer;
depositing a first insulation layer on the entire surface of said substrate with a PECVD technology;
depositing a first reflective metal layer on the entire surface of said substrate, said first reflective metal layer is deposited on the surface of said first insulation layer;
planarizing the surface of said substrate and refilling said plural trenches by coating an second insulation layer on the entire surface of said substrate, therein, said second insulation layer is deposited on the surface of said first reflective metal layer;
removing part of said secondary insulation layer with etching technology, therein, only said second insulation layer formed inside said plural trenches is remained after this step;
removing part of said first reflective metal layer with etching technology, therein, only said first reflective metal layer formed inside said plural trenches is remained after this step;
depositing a passivation layer on the entire surface of said substrate;
patterning a plurality of contact window areas on the surface of said passivation layer with photolithography technology;
forming a plurality of contact windows by removing said passivation layer and said first insulation layer exposed to said plural contact window areas with etching technology;
depositing a second metal layer on the entire surface of said substrate;
patterning a plurality of metal bonding pad areas on the surface of said second metal layer with photolithography technology;
forming a plurality of metal bonding pads by removing part of said second metal layer with etching technology, therein, only said second metal layer formed in said plural metal bonding pad areas is remained after this step; and
depositing a third metal layer on the backside of said substrate as a backside metal layer.

9. The method of fabricating a light emitting diode array according to claim 8, therein, said substrate is formed of III-V compound semiconductor materials.

10. The method of fabricating a light emitting diode array according to claim 8, therein, said PN junction layer is formed of Ill-V compound semiconductor materials whose energy gaps are higher than said substrate.

11. The method of fabricating a light emitting diode array according to claim 8, therein, said first insulation layer is silicon nitride or silicon oxide.

12. The method of fabricating a light emitting diode array according to claim 8, therein, said second insulation layer is polyimide or spin-on glass.
